(19) United States
(12) Patent Application Publication
(10) Pub. No.: US 2010/0141379 A1
(43) Pub. Date: Jun. 10, 2010

(54) Modular Rack Controllers for Patching Systems

(76) Inventors: Peter T. Tucker, Dallas, TX (US); Daniel W. Macauley, Fishers, IN (US); Danny L. Satterthwaite, Allen, TX (US)

Correspondence Address: MYERS BIGEL SIBLEY & SAJOVEC, P.O. BOX 37428, RALEIGH, NC, 27612, US

(21) Appl. No.: 12/630,913

(22) Filed: Dec. 4, 2009

Related U.S. Application Data
(60) Provisional application No. 61/120,197, filed on Dec. 5, 2008.

(51) Int. Cl. G05B 23/02; H05K 5/00

(52) U.S. Cl. 340/3.1; 361/679.02

(57) ABSTRACT

A modular rack controller for an intelligent patching system includes a base unit comprising a processor and memory that monitor and log patch cord connectivity in the patching system, and a separate display unit comprising a user interface. The base unit and display unit are in electrical communication with each other via a patch cord, and the display unit displays patch cord connectivity information monitored by the base unit. The rack controller may include a separate Ethernet interface unit that allows the rack controller to communicate with other rack controllers. A mounting bracket having front and rear sides is mounted to a patch panel rack. The display unit is secured to the front side of the mounting bracket and the base unit is secured to the rear side of the mounting bracket. The mounting bracket may have a hinge that pivots the display unit relative to a patch panel rack.

### RELATED APPLICATION

This application claims the benefit of and priority to U.S. Provisional Patent Application No. 61/120,197, filed Dec. 5, 2008, the disclosure of which is incorporated herein by reference as if set forth in its entirety.

### FIELD OF THE INVENTION

The present invention relates generally to communications systems and, more particularly, to communications patching systems.

### BACKGROUND

Many businesses have dedicated communications systems that enable computers, servers, printers, facsimile machines and the like to communicate with each other, through a private network, and with remote locations via a telecommunications service provider. In, for example, commercial office buildings, the dedicated communications system may be hard wired using communications cables that contain conductive wire. In such hard wired systems, individual connector ports such as modular wall jacks are mounted in offices throughout the building. Communications cables are run through, for example, the walls and/or ceilings of the building to electrically connect each connector port to network equipment (e.g., network servers) that are located in, for example, a telecommunications closet or computer room. Communications cables from external telecommunication service providers may also terminate within the computer room or telecommunications closet.

Communications patching systems are often used to interconnect the various communication cables within a computer room or telecommunications closet. These communications patching systems may facilitate terminating the cables in an organized fashion, and may also simplify the process for later making changes to the connections between communications cables. Typically, a communications patching system includes one or more mounting frames, usually in the form of equipment racks. Network equipment such as, for example, network servers and switches may be mounted on these mounting frames, as may one or more “patch panels.” As is known to those of skill in the art, a “patch panel” refers to an interconnect device that includes a plurality of connector ports such as, for example, communications jacks or fiber optic couplers on at least one side thereof. Each connector port (e.g., a jack) is configured to receive a communications cable that is terminated with a mating connector (e.g., a plug). One or more communications cables may also be terminated into a reverse side of the patch panel (the communications wires of each cable can be terminated into individual contacts or couplers such as, for example, insulation displacement contacts that are often used to terminate the conductors of a twisted pair cable, or may be terminated using a connector port such as would be the case with an RJ-45-to-RJ-45 patch panel). Each connector port on the patch panel may provide communications paths between a communications cable that is plugged into the connector port and a respective one of the communications cables that is terminated into the reverse side of the patch panel. Communications patching systems are typically used to connect individual connector ports in offices throughout the building to, for example, network equipment in the computer room of the building.

FIG. 1 is a simplified example of one way in which a computer 26 in an office or other room 4 of a building may be connected to network equipment 52, 54 located in, for example, a computer room 2 of the building. As shown in FIG. 1, the computer 26 is connected by a patch cord 28 to a modular wall jack 22 that is mounted in a wall plate 24 in office 4. A communications cable 20 is routed from the back end of the modular wall jack 22 through, for example, the walls and/or ceilings of the building, to the computer room 2. As there will often be hundreds or thousands of wall jacks 22 within an office building, a large number of cables 20 are routed into the computer room 2.

A first equipment rack 10 is provided within the computer room 2. A plurality of patch panels 12 are mounted on the first equipment rack 10. Each patch panel 12 includes a plurality of connector ports 16. In FIG. 1, each connector port 16 comprises a modular RJ-45 jack that is configured to receive a modular RJ-45 plug connector. However, it will be appreciated that other types of patch panels may be used such as, for example, patch panels with optical fiber connector ports 16 (e.g., SC, ST, and LC ports) or patch panels with other types of twisted copper wire pair connector ports 16 (e.g., RJ-11 ports).

As shown in FIG. 1, each communications cable 20 that provides connectivity between the computer room 2 and the various offices 4 in the building is terminated onto the back end of one of the connector ports 16 of one of the patch panels 12 on equipment rack 10. A second equipment rack 30 is also provided in the computer room 2. A plurality of patch panels 12′ that include connector ports 16′ are mounted on the second equipment rack 30. A first set of patch cords 40 (only two exemplary patch cords 40 are illustrated in FIG. 1) are used to interconnect connector ports 16 on the patch panels 12 to respective ones of the connector ports 16′ on the patch panels 12′. The first and second equipment racks 10, 30 may be located in close proximity to each other (e.g., side-by-side) to simplify the routing of the patch cords 40.

As is further shown in FIG. 1, network equipment such as, for example, one or more switches 52 and network routers and/or servers 54 (“network devices”) are mounted on a third equipment rack 50. Each of the switches 52 may include a plurality of connector ports 53. A second set of patch cords 60 connect the connector ports 53 on the switches 52 to the back end of respective ones of the connector ports 16′ on the patch panels 12′. As is also shown in FIG. 1, a third set of patch cords 64 may be used to interconnect other of the connector ports 53 on the switches 52 with connector ports 55 provided on the network devices 54. In order to simplify FIG. 1, only a single patch cord 60 and a single patch cord 64 are shown. Finally, one or more external communications lines 66 are connected to, for example, one or more of the network devices 54. In many instances, the communication lines 66 would terminate onto a patch panel and be connected to the network device 54 via a patch cord. For simplicity, the external communication line 66 is pictured as a cable/cord 66 in FIG. 1, which may be the actual external communication line or, alternatively, may be a patch cord that is connected to a patch panel connector port which the actual external communication line is terminated into.

The communications patching system of FIG. 1 may be used to connect each computer, printer, facsimile machine and the like 26 located throughout the building to local area network (“LAN”) switches 52, the LAN switches 52 to network routers 54, and the network routers 54 to external communications lines 66, thereby establishing the physical connectivity required to give devices 26 access to both local and wide area networks. In the patching system of FIG. 1, connectivity changes are typically made by rearranging the patch cords 40 that interconnect the connector ports 16 on the patch panels 12 with respective connector ports 16′ on the patch panels 12′.

The equipment configuration shown in FIG. 1, in which each wall jack 22 is connected to the network equipment 52, 54 through at least two patch panels 12, 12′, is referred to as a “cross-connect” patching system. In another commonly used equipment configuration, which is typically referred to as “inter-connect” patching system, the communications path from each modular wall jack 22 to the network devices 54 typically passes through a single patch panel 12.

FIG. 2 depicts a simplified version of an inter-connect patching system that is used to connect a plurality of computers 126 (and other networked equipment) located in the various offices 104 throughout an office building to a plurality of network devices 154 that are located in a computer room 102 of the building. As shown in FIG. 2, a plurality of patch panels 112 are mounted on a first equipment rack 110. Each patch panel 112 includes a plurality of connector ports 116. A plurality of communications cables 120 are routed from wall jacks 122 in offices 104 into the computer room 102 and connected to the reverse side of the patch panels 112. The computers 126 are connected to respective modular wall jacks 122 by patch cords 128.

As is further shown in FIG. 2, network equipment such as, for example, one or more network devices 154, are mounted on a second equipment rack 150. One or more external communications lines 166 are connected (typically through one or more patch panels and patch cords) to one or more of the network devices 154. A plurality of switches 152 that include a plurality of connector ports 153 are also provided. The switches 152 may be connected to the network devices 154 using a first set of patch cords 164 (only one patch cord 164 is shown in FIG. 2). A second set of patch cords 160 (only one patch cord 160 is shown in FIG. 2) are used to interconnect the connector ports 116 on the patch panels 112 with respective ones of the connector ports 153 on the switches 152. In the patching system of FIG. 2, connectivity changes are typically made by rearranging the patch cords 160 that interconnect the connector ports 116 on the patch panels 112 with respective connector ports 153 on the switches 152.

“Intelligent” patch panels are now available that are capable of automatically determining when a patch cord is plugged into or removed from any of their connector ports. These intelligent patch panels can also determine, either by themselves or in conjunction with a rack controller (which is discussed below), the specific connector port on another patch panel or network switch that a patch cord that is plugged into a connector port on a first patch panel or switch is connected to. Intelligent patching systems which provide such automatic connectivity tracking capabilities are described, for example, in U.S. Pat. Nos. 6,350,148 and 6,222,908.

A rack controller for intelligent patching systems may be mounted to an equipment rack of intelligent patch panels and is used to collect and store information about patch cord insertions and removals occurring at these intelligent panels. A rack controller may communicate with other rack controllers to exchange information about inter-rack patching activity.

An exemplary rack controller 200 for an intelligent patching system is illustrated in FIG. 3. The illustrated rack controller 200 includes an LCD display 202 that displays information about patching activity in progress (i.e., what patch cords are being inserted and removed from what connector ports, etc.), patch cord trace activity in progress, and electronic work orders for new patching activity that have been issued, etc. Typically, a technician can read a log of patch cord changes directly from the rack controller display 202 or can remotely access the log via a remote computer in communication with the rack controller 200. Typically, the rack controller 200 also provides a network interface by which local patching and system status information can be conveyed via Ethernet (or other networking technologies) to patching system management software applications, and by which electronic work orders can be received from such management applications. Conventional rack controllers, such as rack controller 200, may also provide a keypad interface that allows users to view detailed information about circuits being traced, to run diagnostic tests on patch panels, and to select the language used on the display 202, among other functions. Conventional rack controllers, such as rack controller 200, include a processor that executes software or firmware for implementing the various functions described above.

Rack space within wiring closets is becoming increasingly valuable. Because conventional rack controllers typically occupy multiple spaces within a patch panel rack, it would be desirable to reduce the footprint of conventional rack controllers. In addition, conventional rack controllers typically include Ethernet circuitry for connection to the Ethernet LAN of a building. However, only one rack controller in a wiring closet is conventionally connected to the Ethernet LAN of a building. As such, when multiple rack controllers are utilized in a wiring closet, the Ethernet circuitry in the additional rack controllers is not utilized and is an extra cost. Moreover, the Ethernet circuitry in conventional rack controllers may not be modifiable when a customer wishes to upgrade to newer LAN technologies. Typically, a new rack controller has to be purchased.

### SUMMARY

It should be appreciated that this Summary is provided to introduce a selection of concepts in a simplified form, the concepts being further described below in the Detailed Description. This Summary is not intended to identify key features or essential features of this disclosure, nor is it intended to limit the scope of the invention.

According to some embodiments of the present invention, a modular rack controller for an intelligent patching system includes a base unit comprising a processor and memory that monitor and log patch cord connectivity in the patching system, and a separate display unit comprising a user interface. The base unit and display unit are in electrical communication with each other via a patch cord, and the display unit is configured to display patch cord connectivity information monitored by the base unit. In some embodiments, the rack controller includes a separate Ethernet interface unit that is in electrical communication with the base unit.

In some embodiments, a mounting bracket having front and rear sides is configured to be mounted to a patch panel rack. The display unit is secured to the front side of the mounting bracket, and the base unit and, optionally, an Ethernet interface unit, is secured to the rear side of the mounting bracket. The Ethernet interface unit, if included, and base unit are in electrical communication with each other.

In other embodiments, a mounting bracket with a hinge mechanism is configured to be secured to a patch panel rack. A display unit is secured to the mounting bracket and is pivotable relative to the patch panel rack between a first position overlying and covering a portion of a patch panel that is secured to the patch panel rack and a second position extending away from the patch panel and permitting access to the patch panel.

According to some embodiments of the present invention, a communications patching system includes a cabinet having an interior space, a door pivotally secured to the cabinet and movable between a closed position closing the cabinet interior space and an open position exposing the cabinet interior space, a patch panel rack disposed within the cabinet interior space, the patch panel rack having a front portion and a rear portion, one or more patch panels secured to the front portion of the rack, and a modular rack controller. The modular rack controller includes a base unit secured to the rear portion (e.g., to one of the vertical rails, etc.) of the rack or to some other structure within the cabinet (e.g., on the inside wall of the cabinet, etc.). The base unit comprises a processor and memory that monitor and log patch cord connectivity in the patching system. A display unit is secured to the cabinet door, and includes a user interface. The base unit and display unit are in electrical communication with each other via a patch cord, and the display unit is configured to display patch cord connectivity information monitored by the base unit. In some embodiments, the door includes an aperture formed therein, and the display unit is secured to an inside surface of the door and is visible through the aperture.

According to some embodiments of the present invention, a communications patching system includes a plurality of patch panel racks in adjacent, spaced-apart relationship. Each rack supports one or more patch panels and a respective panel bus extender. A rack controller is supported by one of the racks and is electrically connected to each of the panel bus extenders. The rack controller is configured to monitor and log patch cord connectivity in all of the patch panels via the panel bus extenders.

According to some embodiments of the present invention, a communications patching system includes a patch panel rack, one or more patch panels secured to the rack, a rack controller secured to the rack that monitors and logs patch cord connectivity in the patching system, and one or more environment monitors. The rack controller comprises a monitor interface module that collects measurement data from the one or more environment monitors. Exemplary environment monitors include, but are not limited to, temperature monitors, humidity monitors, airflow monitors, water/flood detection monitors, smoke monitors, physical movement monitors, power consumption monitors, and the like. The monitor interface module is configured to process incoming data from the one or more monitors and to detect threshold violations of the incoming data.

In some embodiments, the monitor interface module is configured to send commands to one or more devices, wherein the commands direct the one or more devices to perform a function. For example, a patch panel rack may be located within a cabinet having a locking door. The monitor interface module collects data from the locking door as to whether the door is locked or unlocked. The monitor interface module is also configured to send lock and unlock commands to the door that cause the door to lock if unlocked and to unlock if locked.

According to some embodiments of the present invention, a communications patching system includes a cabinet having a locking door. A patch panel rack is located within the cabinet and one or more patch panels secured to the rack. A rack controller is also secured to the rack, and is configured to monitor and logs patch cord connectivity for the one or more patch panels. The rack controller includes a monitor interface module that collects data from the locking door as to whether the door is locked and/or unlocked. The monitor interface module is also configured to send lock and/or unlock commands to the locking door. The rack controller monitors and logs who performs patch cord changes when the door is unlocked. As such, unauthorized patching changes and/or erroneous patching changes can be attributed to particular personnel.

It is noted that aspects of the invention described with respect to one embodiment may be incorporated in a different embodiment although not specifically described relative thereto. That is, all embodiments and/or features of any embodiment can be combined in any way and/or combination. Applicant reserves the right to change any originally filed claim or file any new claim accordingly, including the right to be able to amend any originally filed claim to depend from and/or incorporate any feature of any other claim although not originally claimed in that manner. These and other objects and/or aspects of the present invention are explained in detail in the specification set forth below.

### BRIEF DESCRIPTION OF THE DRAWINGS

FIG. 1 is a schematic view of a simplified prior art cross-connect communications patching system.

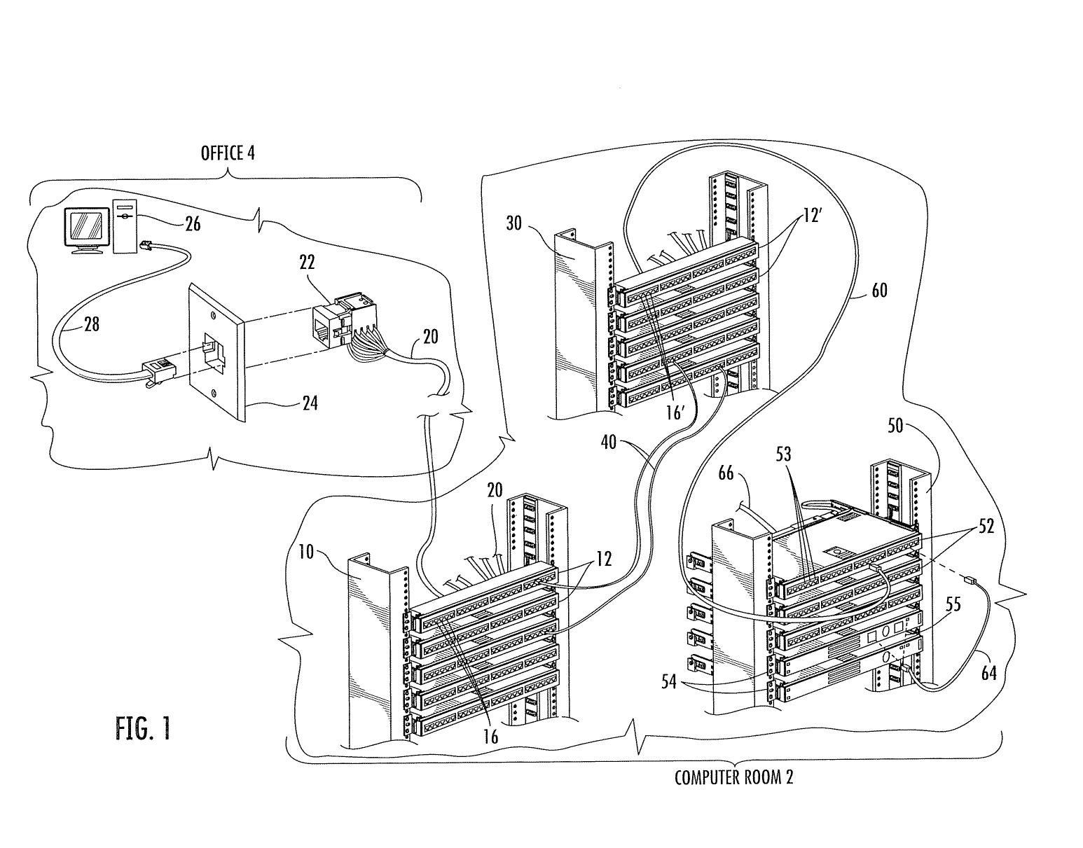

FIG. 2 is a schematic view of a simplified prior art inter-connect communications patching system.

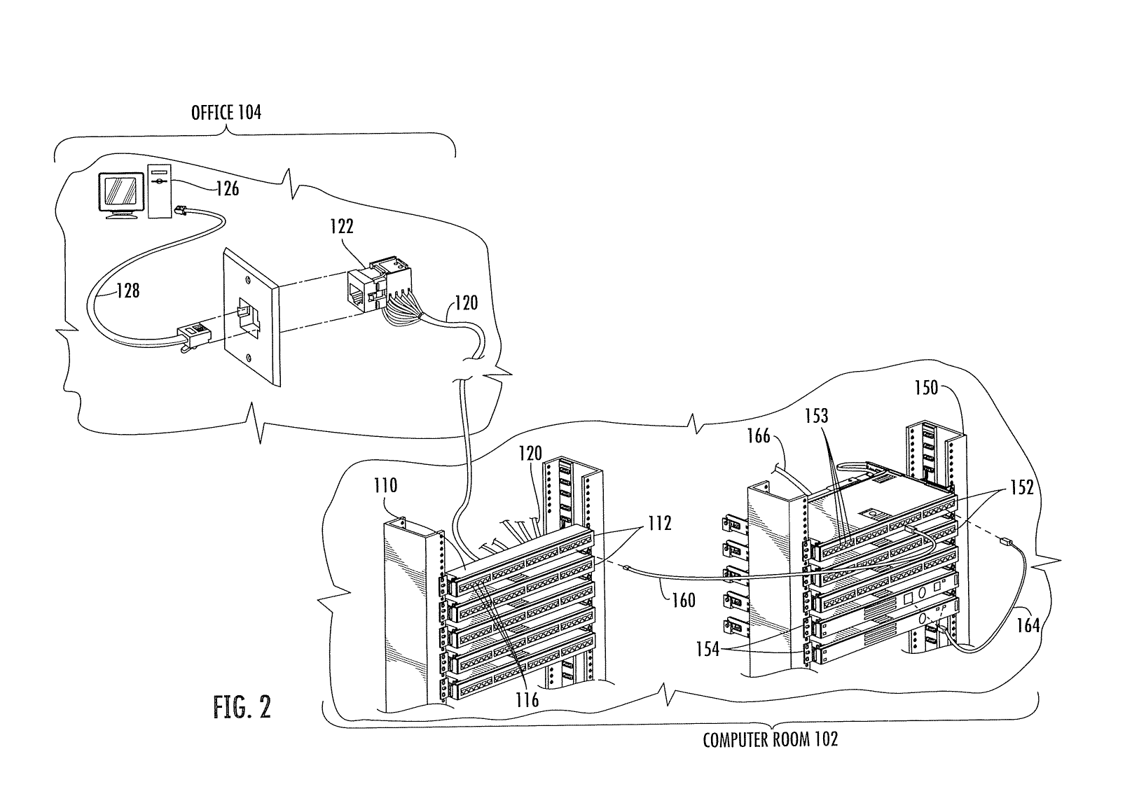

FIG. 3 is a front plan view of a conventional rack controller for a patching system.

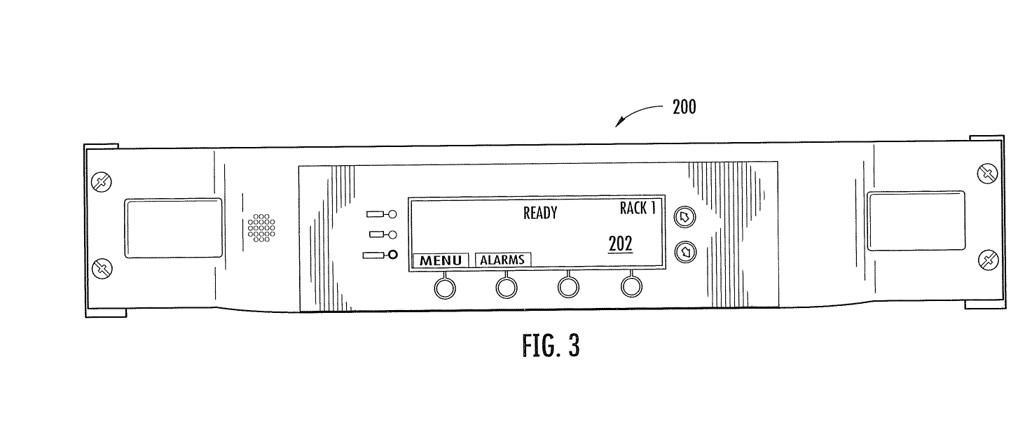

FIG. 4 illustrates a modular rack controller, according to some embodiments of the present invention.

FIG. 5 is a perspective view of a mounting bracket that supports the modular rack controller of FIG. 4, according to some embodiments of the present invention.

FIGS. 6A-6B are perspective views of a mounting bracket that supports the modular rack controller of FIG. 4, according to other embodiments of the present invention.

FIG. 7 is a top plan view of a patch panel rack located within a cabinet, wherein the display unit of the modular rack controller of FIG. 4 is secured to the cabinet door, and wherein the base unit of the rack controller is secured to a back rail of the rack.

FIG. 8 is a front view of a plurality of adjacent patch panel racks, wherein each rack includes at least one patch panel and a respective panel bus extender, according to some embodiments of the present invention.

### DETAILED DESCRIPTION

The present invention now is described more fully hereinafter with reference to the accompanying drawings, in which some embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art.

Like numbers refer to like elements throughout. In the figures, the thickness of certain lines, layers, components, elements or features may be exaggerated for clarity.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. As used herein, the term “and/or” includes any and all combinations of one or more of the associated listed items.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the specification and relevant art and should not be interpreted in an idealized or overly formal sense unless expressly so defined herein. Well-known functions or constructions may not be described in detail for brevity and/or clarity.

It will be understood that when an element is referred to as being “on”, “attached” to, “connected” to, “coupled” with, “contacting”, etc., another element, it can be directly on, attached to, connected to, coupled with or contacting the other element or intervening elements may also be present. In contrast, when an element is referred to as being, for example, “directly on”, “directly attached” to, “directly connected” to, “directly coupled” with or “directly contacting” another element, there are no intervening elements present.

It will be understood that, although the terms “first”, “second”, etc. may be used herein to describe various elements, components, patch panels, etc., these elements, components, patch panels etc. should not be limited by these terms. These terms are only used to distinguish one element, component, patch panel, etc. from another element, component, patch panel. Thus, a “first” element, component, or patch panel discussed below could also be termed a “second” element, component, or patch panel without departing from the teachings of the present invention. In addition, the sequence of operations (or steps) is not limited to the order presented in the claims or figures unless specifically indicated otherwise.

### Modular Rack Controller

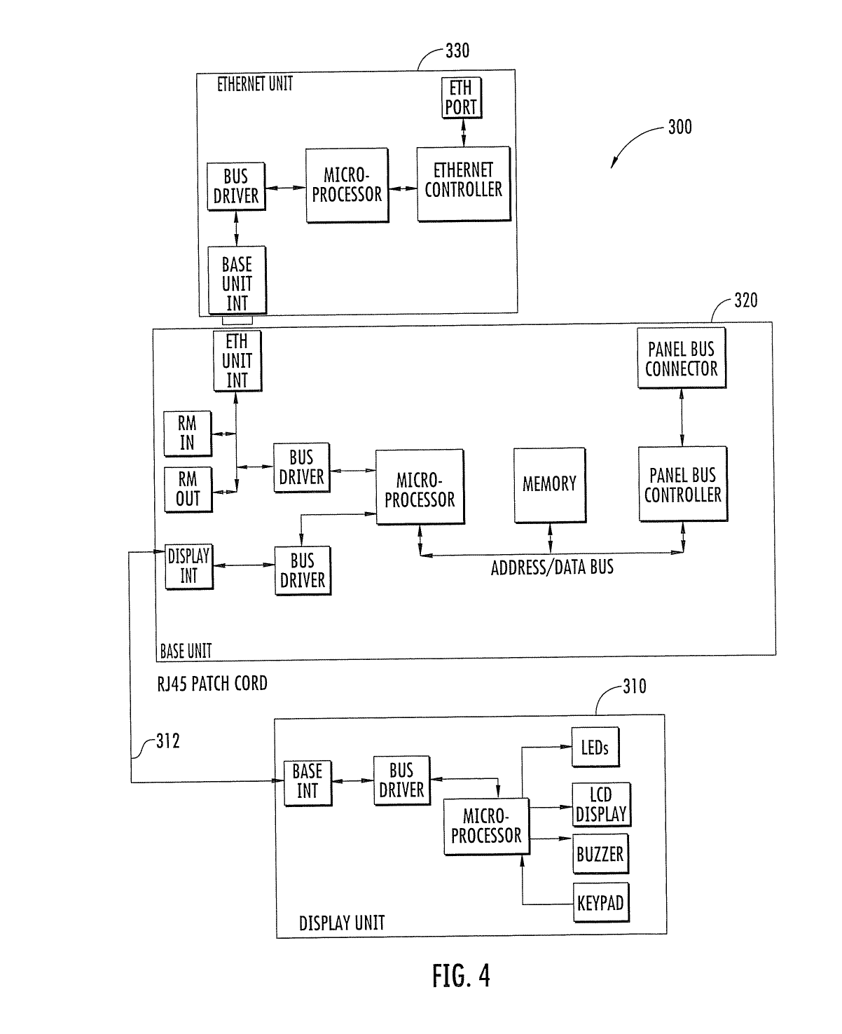

Referring to FIG. 4, a modular rack controller 300, according to some embodiments of the present invention, is illustrated. The illustrated rack controller 300 has three physically separate units: a base unit 320 which contains the rack controller's microprocessor, memory, and panel interfaces, a display unit 310 which provides the rack controller's user interface functions (e.g., LCD display screen, keypad, speaker, and status LEDs), and an optional Ethernet interface unit 330. The base and display units 320, 310 communicate with one another via an RS-485 interface routed over a standard RJ-45 (or other type) patch cord 312, with the base unit 320 providing power to the display unit 310 over this interface. The optional Ethernet interface unit 330 sits on the same bus that is used by the rack controller 300 to communicate with other rack controllers residing on adjacent equipment racks. In some embodiments, the Ethernet interface unit 330 is powered from an independent AC power adapter, and is connected to the rack controller LAN daisy chain. In other embodiments, the Ethernet interface unit 330 can be mated to another rack controller and receive power from that unit.

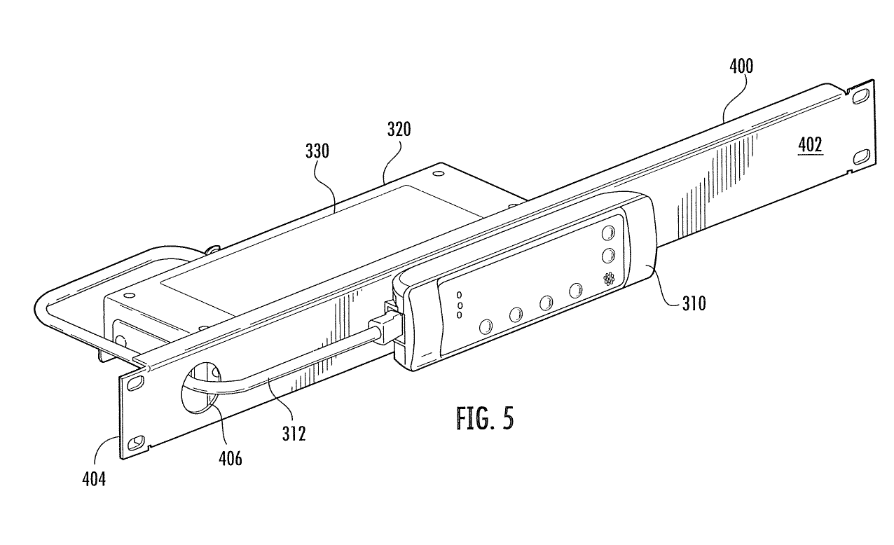

Referring to FIG. 5, a mounting bracket 400 that fits in a standard equipment rack and that takes up 1U (one unit) of space, according to some embodiments of the present invention, is illustrated. As known to those of skill in the art of the present invention, the height of electronic equipment or patch panels mounted in 19″ equipment racks is standardized in the industry to be equal to or a multiple of 1.75″. By convention, equipment or panels that are 1.75″ high are said to occupy 1 “rack unit.” Similarly, equipment or patch panels that are 3.5″ high are said to occupy 2 “rack units” (2U), etc.

The bracket 400 is configured to position the display unit 310 of the modular rack controller 300 of FIG. 4 on the front side of a rack (not shown), and the base unit 320 and Ethernet unit 330 on the rear side of the rack. The illustrated mounting bracket 400 includes a front surface 402 to which the display unit 310 is mounted and a rear surface 404 to which the base unit 320 is mounted. An aperture 406 is formed through the bracket 400, as illustrated. Patch cord 312 extends through the aperture 406 and connects the display unit 310 and base unit 320 together. As described above, the Ethernet unit 330 is optional for the modular rack controller 300, and need only be included when the rack controller 300 is to handle communications with the intelligent patching system's management software for the patch panels located in the wiring closet.

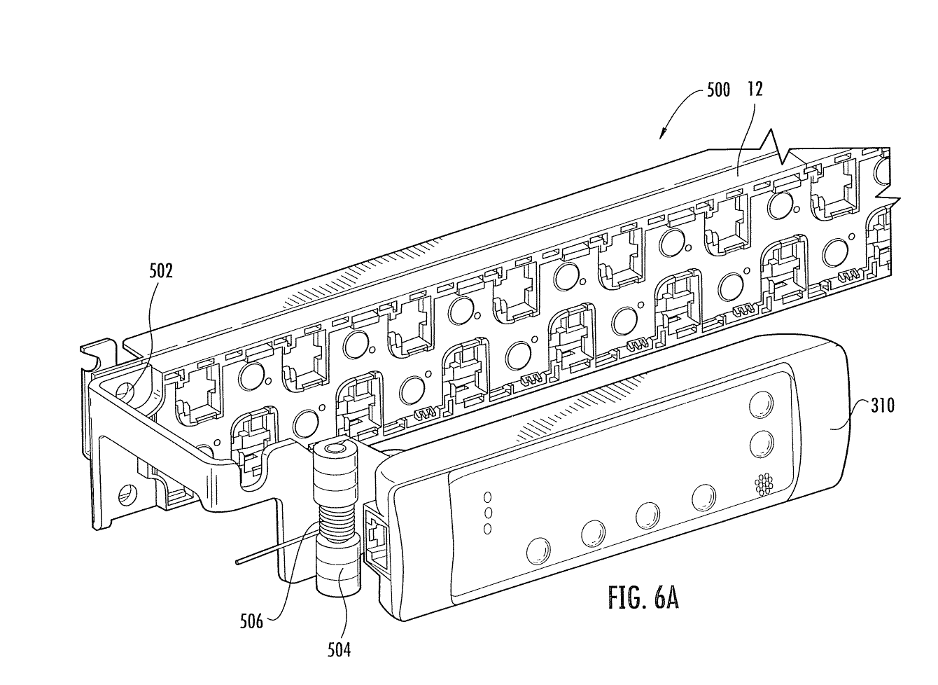

Referring to FIGS. 6A-6B, a display unit mounting bracket 500 associated with a patch panel for supporting a display unit 310, according to other embodiments of the present invention, is illustrated. The illustrated patch panel 12 is configured to be mounted on a rack (not shown) using fasteners (not shown), such as screws, etc. During installation on a rack, the display unit mounting bracket 500 is positioned such that apertures 502 in the bracket 500 align with corresponding apertures in the end portion of the patch panel 12. Fasteners are inserted within the apertures 502 to attach both the patch panel 12 and the display unit mounting bracket 500 to the front side of a rack. A base unit 320 and (optional) Ethernet unit 330 (not shown) can be mounted on the back side of the rack. In some embodiments, depending on the design of the particular rack or cabinet, the base and Ethernet units 320, 330 could be secured to the back side of one of the rack rails. In other embodiments, an arcuate (e.g., U-shaped, etc.) bracket (not shown) can be used to ensure that the base and Ethernet units 320, 330 do not interfere with cables that are terminated to the back side of patch panel 12 (or other patch panels on the rack mounted above or below patch panel 12) and that are typically routed to cable troughs on either side of the rack, passing in close proximity to the back sides of the rack rails.

The illustrated bracket 500 has a hinge mechanism 506 that is pivotable between first and second positions. When the hinge mechanism 506 is in the first position, the display unit 310 overlies and covers a portion of a patch panel 12 secured to the patch panel rack (not shown), as illustrated in FIG. 6A. When the hinge mechanism 506 is in the second position, the display unit 310 is pivoted away from a patch panel 12 to allow access to the patch panel, as illustrated in FIG. 6B. In the illustrated embodiment, the hinge mechanism 506 maintains the display unit 310 in spaced-apart, adjacent relationship with the patch panel 12. Thus, the hinge mechanism 506 allows the display unit 310 to be conveniently located for displaying information about a patching system and to be easily moved out of the way to facilitate access to a patch panel 12 (or other device) as needed.

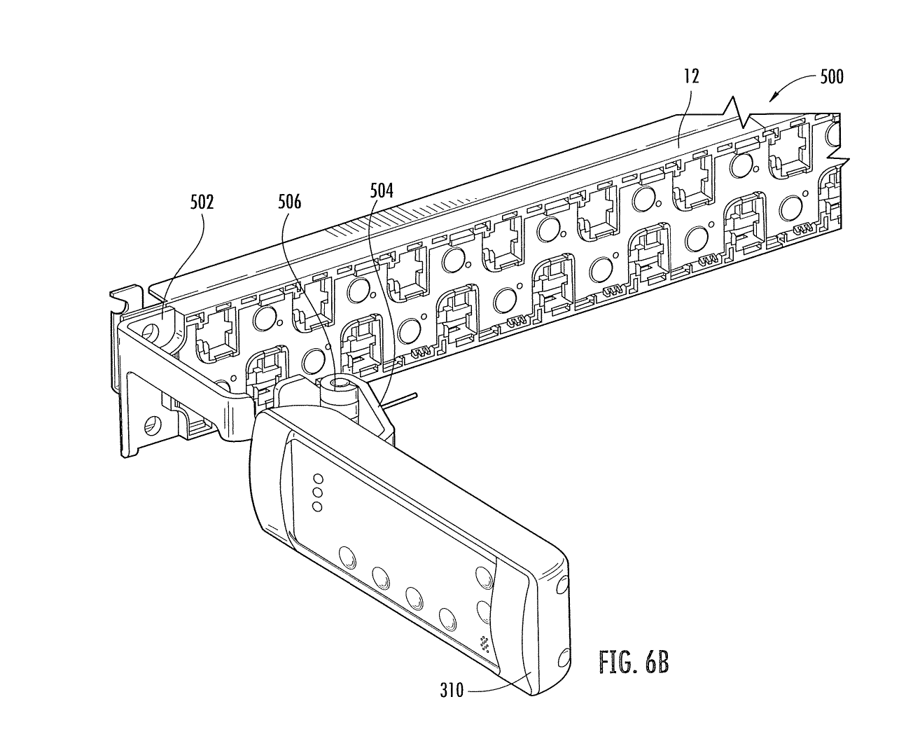

Referring to FIG. 7, according to other embodiments of the present invention, the base and Ethernet units 320, 330 of the modular rack controller 300 of FIG. 4 are configured to be mounted to the back rail 602 of an equipment rack 600. The illustrated rack 600 is located within a cabinet 604 having a door 606 that is movable between closed and open positions. In FIG. 7, the cabinet door 606 is in a closed position.

The display unit 310 is mounted on the inside of the cabinet door 606 and is visible through an aperture (not shown) in the cabinet door 606. In some embodiments, the display unit 310 is movably secured to the cabinet door 606 and is configured to rotate when the cabinet door 606 is moved between closed and open positions such that the display unit 310 is visible through the door aperture when the cabinet door 606 is closed and such that the display unit 310 is visible through the door aperture when the cabinet door 606 is open. As illustrated in FIG. 7, when the cabinet door 606 is closed, the display unit 310 overlies and covers a portion of a patch panel 12 secured to the patch panel rack 600. The illustrated display unit 310 is connected to the base unit 320 via a patch cord 312.

### Panel Bus Extenders

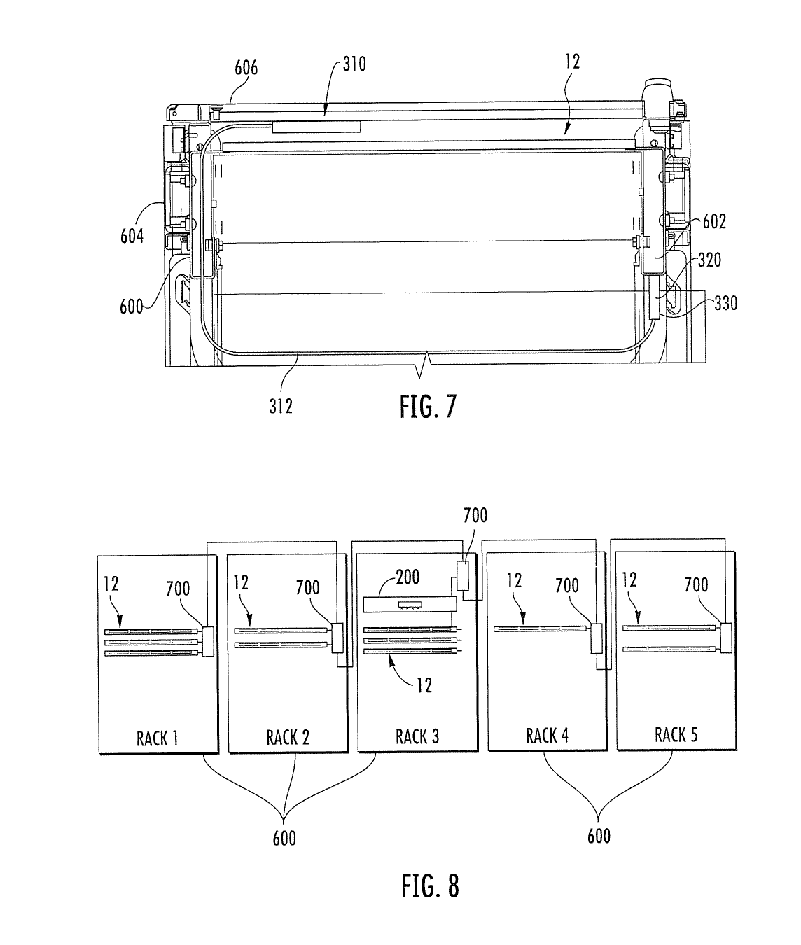

In certain types of installations, one or more racks in a wiring closet may contain only a few patch panels 12. The use of a single rack controller for each rack, particularly when only a few patch panels 12 are mounted to each rack, can be expensive. According to embodiments of the present invention, a rack controller can include one or more panel bus extenders that can be mounted on adjacent racks in a wiring closet and can allow a single rack controller to support patch panels 12 on these adjacent racks. FIG. 8 illustrates a conventional rack controller 200 coupled to a plurality of panel bus extenders 700 on four adjacent racks 600, according to other embodiments of the present invention. The rack controller 200 collects and stores information about patch cord insertions and removals occurring at the patch panels on these adjacent racks via the panel bus extenders 700.

The panel bus in a patch panel 12 uses an industry standard bus referred to as I2C. This bus is traditionally used to connect up electronics that are separated by very short distances, typically less than 3 meters. The panel bus extenders 700 of the present invention utilize integrated circuits that amplify the I2C bus signals, thus making it possible to extend the range of the panel bus to 60 meters, thus making it possible to extend the panel bus from one rack controller 200 to a couple of adjacent racks to either side of the rack holding the controller 200. As such, the use of bus extenders 700 can reduce the number of rack controllers 200 required in a patching system.

### Monitoring

According to other embodiments of the present invention, a rack controller can be configured to perform various monitoring functions including, but not limited to, environmental monitoring, access monitoring, etc. Exemplary environmental conditions that can be monitored include, but are not limited to, temperature, humidity, airflow, water/flood detection, and smoke detection. Other conditions within a cabinet and/or computer room that can be monitored include, but are not limited to, electrical power consumption, cabinet door open/close detection, and equipment movement (e.g., vibration, physical movement of a patch panel, patch cord, switch, router, etc.).

A rack controller, according to some embodiments of the present invention, can include one or more sensor interface modules that are configured to collect and report raw sensor measurement data. The rack controller includes firmware configured to process incoming sensor data, monitor sensor thresholds, and report any threshold violations to patch panel management software. The management software can use existing Simple Network Manager Protocol (SNMP) capabilities to notify network management systems of environmental or other alarm conditions.

Sensors can either be built into a rack controller base unit itself, or can be attached to a panel bus, such that they would receive power from and communicate with the rack controller in a fashion similar to the patch panels themselves. A hybrid approach, where the most commonly used sensors would be built directly into the rack controller base unit, while less common sensors could be added to a rack's panel bus, is also possible.

According to other embodiments of the present invention, control interface modules that plug into an existing rack controller panel bus can be used to receive commands from the rack controller firmware by way of the panel bus to perform various functions. For example, a control interface module can have the ability to unlock a cabinet door upon command from a local rack controller which in turn can respond to commands issued by patch panel management software from a remote location.

According to some embodiments of the present invention, a cabinet door has a latching mechanism that can be moved between open and closed states via either a servo motor, or electromagnets also present in the door. A control unit that could detect whether the door is in the locked or unlocked state, and which would also have the ability to drive the servo motor or electromagnets in the cabinet door, would be attached to the panel bus. A rack controller would be able to query this controller via messages sent over the panel bus to determine the current state of the door lock, and could also issue commands to the controller to move the lock to the open or closed position. Upon receipt of such a command, the controller would issue the appropriate control signals to the servo motor or electromagnets to drive the door lock into the desired state (locked or unlocked).

In some embodiments, a technician is sent a patching work order via email that contains a job ID and a password. Upon arriving at the wiring closet where the job is to be performed, the technician finds the electronic job on the rack controller's work queue, and enters the password received in the email in order to unlock the cabinet door(s).

In some embodiments, a patching system is able to detect whether a technician moved any patch cords other than the ones specified in a work order while the cabinet doors were unlocked, and can report any illicit patching changes to an administrator. In other embodiments, a technician may be given a unique code that would allow him/her to unlock any cabinet door at their site. Any patching change that occurred while the door was opened would be attributed to the technician whose code was used to open the door. This would allow administrators to determine who was responsible for making any particular patching change that occurred at their site.

Table 1 lists various functions that can be supported according to some embodiments of the present invention.

TABLE 1

Remote locking/unlocking of cabinet doors
Remote relay closure that allows a customer to turn
power on/off to any equipment they choose to connect
to the closure device
Visual/audio warning device activation based on error
conditions detected locally by rack controller, or based
on instructions received from patch panel
management software

According to other embodiments, a cabinet housing a rack of patch panels therein may be configured to perform various monitoring functions including, but not limited to, environmental monitoring, access monitoring, etc. Exemplary environmental conditions that can be monitored include, but are not limited to, temperature, humidity, airflow, water/flood detection, and smoke detection. Other conditions that can be monitored include, but are not limited to, electrical power consumption, cabinet door open/close detection, and movement (e.g., vibration, physical movement, etc.). Monitoring equipment can be mounted into the ceiling or flooring of a cabinet to avoid using rack mounting space. In other embodiments, the monitoring equipment can be secured to the back side of a patch panel supporting rack within the cabinet.

The foregoing is illustrative of the present invention and is not to be construed as limiting thereof. Although a few exemplary embodiments of this invention have been described, those skilled in the art will readily appreciate that many modifications are possible in the exemplary embodiments without materially departing from the novel teachings and advantages of this invention. Accordingly, all such modifications are intended to be included within the scope of this invention as defined in the claims. The invention is defined by the following claims, with equivalents of the claims to be included therein. The following exemplary claims are presented in the specification to support one or more devices, features, and methods of embodiments of the present invention. While not particularly listed below, Applicant preserves the right to claim other features shown or described in the application.

That which is claimed is:

1. A modular rack controller for a communications patching system, comprising:
a base unit comprising a processor and memory that monitor and log patch cord connectivity in the patching system; and
a separate display unit comprising a user interface, wherein the base unit and display unit are in electrical communication with each other via a cable, and wherein the display unit is configured to display patch cord connectivity information monitored by the base unit.

2. The rack controller of claim 1, wherein the cable is a patch cord.

3. The rack controller of claim 1, wherein the base unit and display unit communicate with each other via an RS-485 interface routed over the patch cord.

4. The rack controller of claim 2, wherein the patch cord is an RJ-45 patch cord.

5. The rack controller of claim 1, further comprising a separate Ethernet interface unit, wherein the Ethernet unit and base unit are in electrical communication with each other.

6. The rack controller of claim 1, further comprising a mounting bracket having front and rear sides, wherein the mounting bracket is configured to be mounted to a patch panel rack, wherein the display unit is secured to the front side of the mounting bracket, wherein the base unit is secured to the rear side of the mounting bracket, and wherein the base unit and display unit are in electrical communication with each other via a patch cord.

7. The rack controller of claim 6, further comprising an Ethernet interface unit secured to the rear side of the mounting bracket, and wherein the Ethernet unit and base unit are in electrical communication with each other, wherein the Ethernet interface is configured to allow the base unit to communicate with each other.

8. The rack controller of claim 1, comprising a mounting bracket with a hinge mechanism configured to be secured to a patch panel rack, wherein the display unit is secured to the mounting bracket and is pivotable relative to the patch panel rack between a first position overlying and covering a portion of a patch panel secured to the patch panel rack and a second position extending away from the patch panel and permitting access to the patch panel.

9. A communications patching system, comprising:
a cabinet having an interior space;
a door pivotally secured to the cabinet and movable between a closed position closing the cabinet interior space and an open position exposing the cabinet interior space;
a patch panel rack disposed within the cabinet interior space, the patch panel rack having a front portion and a rear portion;
one or more patch panels secured to the front portion of the rack; and
a modular rack controller, comprising:
a base unit that comprises a processor and memory that monitor and log patch cord connectivity in the patching system; and
a display unit secured to the cabinet door, wherein the display unit comprises a user interface, wherein the base unit and display unit are in electrical communication with each other via a cable, and wherein the display unit is configured to display patch cord connectivity information monitored by the base unit for the one or more patch panels.

10. The communications patching system of claim 9, wherein the door includes an aperture formed therein, and wherein the display unit is secured to an inside surface of the door and is visible through the aperture both when the door is in a closed position and an open position.

11. A communications patching system, comprising:
a plurality of patch panel racks in adjacent, spaced-apart relationship, wherein each rack supports one or more patch panels and a respective panel bus extender; and
a rack controller supported by one of the racks, wherein the rack controller is electrically connected to each of the panel bus extenders and monitors and logs patch cord connectivity in all of the patch panels via the panel bus extenders.

12. A communications patching system, comprising:
a patch panel rack;
one or more patch panels secured to the rack; and
a rack controller secured to the rack, wherein the rack controller monitors and logs patch cord connectivity for the one or more patch panels, wherein the rack controller comprises a monitor interface module that collects measurement data from one or more environment monitors.

13. The communications patching system of claim 12, wherein the one or more environment monitors are selected from the group consisting of temperature monitors, humidity monitors, airflow monitors, water/flood detection monitors, smoke monitors, physical movement monitors, power consumption monitors.

14. The communications patching system of claim 12, wherein the one or more environment monitors are attached to the rack controller.

15. The communications patching system of claim 12, wherein the monitor interface module is configured to process incoming data from the one or more monitors and to detect threshold violations of the incoming data.

16. The communications patching system of claim 12, wherein the monitor interface module is configured to send commands to one or more devices, wherein the commands direct the one or more devices to perform a function.

17. The communications patching system of claim 12, wherein the monitor interface module is configured to turn off power to user selected equipment associated with the patching system.

18. The communications patching system of claim 12, wherein the patch panel rack is located within a cabinet having a locking door, wherein the monitor interface module collects data from the locking door as to whether the door is locked and/or unlocked, and wherein the monitor interface module is configured to send lock and/or unlock commands to the locking door.

19. A communications patching system, comprising:
a cabinet having a locking door;
a patch panel rack located within the cabinet;
one or more patch panels secured to the rack; and
a rack controller secured to the rack, wherein the rack controller monitors and logs patch cord connectivity for the one or more patch panels, wherein the rack controller comprises a monitor interface module that collects data from the locking door as to whether the door is locked and/or unlocked, wherein the monitor interface module is configured to send lock and/or unlock commands to the locking door, and wherein the wherein the rack controller monitors and logs who performs patch cord changes when the door is unlocked.
